(19) United States
(12) Patent Application Publication
(10) Pub. No.: US 2023/0052543 A1
(43) Pub. Date: Feb. 16, 2023

(54) DECOUPLING RADIOFREQUENCY (RF) SIGNALS FROM INPUT SIGNAL CONDUCTORS OF A PROCESS CHAMBER

(71) Applicant: Lam Research Corporation, Fremont, CA (US)

(72) Inventors: Nick Ray Linebarger, Jr., Beaverton, OR (US); Mohan Thilagaraj, Tualatin, OR (US)

(21) Appl. No.: 17/760,159

(22) PCT Filed: Feb. 9, 2021
(86) PCT No.: PCT/US2021/017227

§ 371 Date: Aug. 4, 2022

Related U.S. Application Data
(60) Provisional application No. 62/972,318, filed on Feb. 10, 2020.

(51) Int. Cl. H01J 37/32

(52) U.S. Cl. CPC H01J 37/32174; H01J 37/32522; H01J 2237/334

(57) ABSTRACT

An apparatus to decouple RF signals from input signal conductors of a process chamber includes at least a first switch to decouple an energy storage element from an active element within a process station. In particular embodiments, while the first switch is in an opened position, a second switch located between a current generator and energy storage element is closed, thereby permitting the current generator to charge the energy storage element. In response to the energy storage element attaining a predetermined voltage, the first switch may be closed, and the second switch may be opened, thereby permitting current to be discharged from the energy storage element to the active element. In certain embodiments, the first and second switches are not permitted to simultaneously operate in a closed position, thereby preventing RF from being coupled from the process station to the current generator.

### CROSS-REFERENCE TO RELATED APPLICATIONS

A PCT Request Form is filed concurrently with this specification as part of the present application. Each application that the present application claims benefit of or priority to as identified in the concurrently filed PCT Request Form is incorporated by reference herein in its entirety and for all purposes.

### BACKGROUND

During wafer fabrication processes, such as etching of a film deposited on a substrate utilizing a multi-station integrated circuit fabrication chamber, one or more radiofrequency (RF) signals may be coupled to process stations of the chamber. Coupling of RF signals of sufficient energy to a process station may bring about or enhance formation of an ionized plasma material. The ionized plasma material may operate to remove or etch material from selected locations of a semiconductor wafer. However, in certain situations, high-energy radiofrequency signals can intrude and/or interfere with other subsystems and/or components of the fabrication chamber. In some instances, such intrusion and/or interference of RF energy can degrade operation of a fabrication chamber or of instruments utilized in connection with the fabrication chamber. In other instances, intrusion of RF energy can represent a parasitic loss of RF energy. In these instances, although the parasitic loss of RF energy may amount to only a small percentage of a total amount of energy generated by a RF signal generator, such parasitic loss represents an unproductive expenditure of RF energy. Thus, approaches toward reducing parasitic losses of RF energy continues to be an active area of investigation.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

General aspects of the claims include an apparatus to couple signals to a process chamber, including: one or more first switches, positioned between at least one energy storage device and at least one active element of the process chamber, which operate to, or configured to, control a first current conducted between the at least one energy storage device and the at least one active element of the process chamber. The apparatus also includes one or more second switches, positioned between the at least one energy storage device and one or more current generators, to control current conduction between the one or more current generators and the at least one energy storage device.

The above-described apparatus can further include one or more radiofrequency (RF) filters, each of the one or more RF filters can be arranged in a series relationship with a corresponding one of the one or more first switches. The one or more RF filters can provide at least about 20 dB of signal attenuation at about 400 kHz and/or at about 27.12 MHz. The at least one energy storage device can include a capacitor. The capacitor of the apparatus can include a capacitance from about 1 mF to about 100 mF. The at least one energy storage device can include an inductor. The inductor of the apparatus can range from about 1 mH to about 100 mH. The apparatus can further include a transformer configured to increase a voltage from the at least one energy storage device. The apparatus can further include a controller coupled to the at least one energy storage device to modify a value of capacitance or inductance of the at least one energy storage device. The energy storage device can include 2 or more energy storage devices arranged in a parallel relationship. The at least one active element of the process chamber can include a resistive heating element. The at least one active element of the process chamber can include a microwave signal generator, an ultraviolet light source, an infrared light source, or any combination thereof. The one or more first switches, a RF filter, the energy storage device, and the one or more second switches can be arranged in a series relation with the one or more current generators. The apparatus can further include a controller configured to prevent closing of the one or more first switches and the one or more second switches at the same time.

In one or more additional aspects, a controller may operate to control switching of one or more first switches and one or more second switches, the controller may include a processor coupled to a memory to direct opening of one or more first switches, positioned between at least one energy storage device and at least one active element of a process chamber. The processor may additionally direct closing the one or more first switches following, or simultaneous with, the opening of one or more second switches, the one or more second switches positioned between the at least one energy storage device and one or more current generators.

The controller can, after a duration, direct opening of the one or more second switches. Following or simultaneously with the opening of the one or more second switches, the controller can bring about closing of the one or more first switches. The controller can additionally operate to modify a value of capacitance or inductance of the at least one energy storage device. The controller can additionally direct closing of the one or more first switches responsive to an indication that the at least one energy storage device has accumulated a predetermined amount of energy.

One or more additional aspects may include a process chamber, including: a first input port to receive a radiofrequency (RF) signal. The process chamber can additionally include a resistive heating element at least partially disposed within the process chamber. The process chamber can additionally include a current generator coupled to an energy storage device to supply an electric current to the resistive heating element. The process chamber can additionally include a first switch, between the energy storage device and the resistive heating element, to interrupt a current coupled from the energy storage device to the resistive heating element. The process chamber can additionally include a second switch, between the current generator and the energy storage device, to interrupt a current coupled from the current generator and the energy storage device.

The process chamber can further include a controller to initiate the opening of the first switch and the closing of the second switch to permit the energy storage device to accumulate charge from the current generator. The controller of the process chamber can additionally close the first switch and open the second switch responsive to the energy storage device storing a predetermined amount of charge. The controller of the process chamber can additionally operate to ensure that the first switch and the second switch are not simultaneously closed. The energy storage device can include one or more capacitors having a total capacitance from about 1 mF to about 100 mF or can include one or more inductors having a total inductance from about 1 mH to about 100 mH. The RF signal received by the first input port can correspond to a signal of about 400 kHz and/or a signal of about 27.12 MHz. The process chamber can include 2 or more wafer-processing stations.

### BRIEF DESCRIPTION OF THE DRAWINGS

The various implementations disclosed herein are illustrated by way of example, and not by way of limitation, in the figures of the accompanying drawings, in which like reference numerals refer to similar elements.

FIG. 1A shows an example apparatus for depositing or etching a film on or over a substrate utilizing any number of processes, according to in embodiment.

FIG. 1B is a schematic view of a multi-station integrated circuit fabrication chamber that utilizes active components, according to an embodiment.

FIG. 2A is a schematic diagram showing first switch states of an example apparatus to decouple RF signals from input signal conductors of a process station of a multi-station integrated circuit fabrication chamber, according to an embodiment.

FIG. 2B is a schematic diagram showing second switch states of the example apparatus shown in FIG. 2A, according to an embodiment.

FIG. 2C shows an example waveform depicting charging and discharging of the energy storage device of FIGS. 2A and 2B, according to an embodiment.

FIG. 3A is a schematic diagram showing energy storage devices arranged in parallel in an apparatus to decouple RF signals from input signal conductors of a process station, according to an embodiment.

FIGS. 3B and 3C show example waveforms depicting charging and discharging of the parallel-connected energy storage devices of FIG. 3A, according to an embodiment.

FIG. 4 is a schematic diagram showing a controller coupled to an energy storage device in an example apparatus to decouple RF signals from input signal conductors of a process station, according to an embodiment.

FIG. 5 is a schematic diagram showing a step-up transformer coupled to an energy storage device in an example apparatus to decouple RF signals from input signal conductors of a process station, according to an embodiment.

FIG. 6 is a flowchart for an example method of decoupling RF signals from input signal conductors of a process chamber, according to an embodiment.

### DETAILED DESCRIPTION

In certain types of integrated circuit fabrication chambers, a radio frequency (RF) power source may be utilized to provide a signal that permits formation of a plasma, which may include ionized gaseous compounds and/or elements, within the fabrication chamber. In a multi-station integrated circuit fabrication chamber, power from a single RF power source may be divided into approximately equal portions so as to provide a signal that permits formation of a plasma at each individual station of the multi-station integrated circuit fabrication chamber. Accordingly, semiconductor wafers may simultaneously undergo material deposition or removal (e.g., etching) processes utilizing a single RF input signal. In particular multi-station integrated circuit fabrication chambers, RF energy may be coupled via a transmission line to a structure placed within each station of the fabrication chamber. Such placement permits formation of an ionizing electric or magnetic field in close proximity with an integrated circuit wafer undergoing fabrication. Thus, ionized plasma may be generated and immediately deployed at and exposed surface of the integrated circuit wafer.

In particular applications, in addition to coupling of RF energy into each station of a fabrication chamber, heat energy may additionally be coupled into each station. In some arrangements, such as described further herein, a resistive heater or other type of active element may be positioned at a pedestal located beneath an integrated circuit wafer undergoing fabrication. Thus, in such arrangements, RF and heat energies coupled to a fabrication station may cooperate to accelerate material deposition and/or material removal (e.g., etching) processes. In addition, by way of separately exercising control over RF energy and heat energy coupled to a fabrication station, deposition/or material removal processes may be tightly controlled. This may, in turn, permit greater process optimization, process repeatability, and so forth.

In particular types of multi-station fabrication chambers, electrical conductors having relatively high current-carrying capabilities may be utilized to convey signals from a current generator to active (e.g., heating) elements within the process station. Under certain circumstances, such electrical conductors may provide a path that permits conduction of RF signals from locations within the fabrication chamber in the direction of the current generator. Thus, RF power introduced into a fabrication chamber may be unintentionally coupled to locations within a fabrication chamber at which the coupled RF power does not benefit or enhance an aspect of fabrication process. In other instances, RF power introduced into a fabrication chamber may be unintentionally drawn to locations external to a fabrication chamber. In many instances, such unwanted coupling of RF power to locations internal or external to a fabrication chamber may represent a parasitic loss of RF power. In some instances, such parasitic loss of RF power may represent between about 1% and 5% of total RF power coupled into a particular station of a fabrication chamber. In some instances, such parasitic loss may vary among stations of a multi-station fabrication chamber. Thus, such variance may represent a source of error in computations related to determining actual amounts of RF power coupled to individual stations of a multi-station fabrication chamber.

Additionally, parasitic coupling of RF power to locations outside of a fabrication chamber may give rise to interference with sensitive electronic circuitry also located outside of a fabrication chamber. For example, in particular types of circuits, such as those in which relatively low-level signals (e.g., voltage magnitudes) are utilized to communicate a parameter, coupling of an RF signal into such circuitry may bring about distortions of signal amplitudes. Such distortions in signal amplitudes may negatively impact control systems. Examples of negative impacts can include unintended process variations, damage to fabrication equipment, or other undesirable consequences. In one particular example, coupling of RF energy to an output signal conductor from a thermocouple may bring about large variations in a reported temperature. Such variations and reported temperature may, in turn, bring about significant variations in current conducted to heating elements located within individual stations of a fabrication chamber.

Thus, for the above-identified reasons, and potentially others, decoupling of RF signals from input signal conductors of a process chamber may provide an approach toward minimizing station-to-station variations in fabrication processes. Decoupling of RF signals from input signal conductors of a process chamber operates to confine RF energy to locations within the fabrication chamber. In particular embodiments, confining RF energy to locations within a fabrication chamber may include use of one or more first switches positioned between at least one energy storage device and at least one active element of the process chamber. The one or more first switches can operate to control a first current conducted between the at least one energy storage device and the at least one active element of the process chamber. An active element of the process chamber may include a heater, for example, but may include other active elements such as microwave signal generators, ultraviolet light sources, infrared light sources, or other energy sources that can impart energy on precursor gases, substrates, or other elements present in a process chamber. One or more second switches may be positioned between the at least one energy storage device and one or more voltage or current generators to control a current conducted between the one or more current generators and the at least one energy storage device.

Through the use of such switches, and a controller configured to exert control over such switches, one or more first switches may be opened so as to decouple a voltage or current generator from the process chamber. Following opening of the one or more first switches, one or more second switches may be closed, which may permit a current source (for example) to charge an energy storage device. Following the energy storage device being charged, the one or more second switches may be opened and the one or more first switches may be closed. Electrical charges may thus be permitted to conduct from the energy storage device into a process station, such as a process station of a multi-station integrated circuit fabrication chamber. In particular embodiments, the controller may operate to prevent closing of the one or more first switches and the one or more second switches at the same time. By preventing the first and second switches from being closed at the same time, parasitic RF signals from a process station may be precluded from being coupled from the process chamber to the current generator. As a consequence of precluding the coupling of RF energy from a process station toward a current generator, the load impedance presented by the process station may remain stable. Accordingly, responsive to a process station presenting a stable load impedance to a RF generator, RF power coupled to the process station may be subject to fewer fluctuations. Thus, RF power coupled to the process station may be stabilized which may result in greater control over fabrication processes, enhanced process repeatability, and so forth.

Certain embodiments and implementations may be utilized in conjunction with a number of wafer fabrication processes, such as various plasma-enhanced atomic layer deposition (PEALD) processes (e.g., PEALD1, PEALD2), various plasma-enhanced chemical vapor deposition (e.g., PECVD1, PECVD2, PECVD3) processes, or may be utilized on-the-fly during single deposition processes. In certain implementations, a RF power generator having multiple output ports may be utilized at any signal frequency, such as at frequencies between 300 kHz and 60 MHz, which may include frequencies of 400 kHz, 440 kHz, 1 MHz, 2 MHz, 13.56 MHz, and 27.12 MHz. However, in other implementations, RF power generators having multiple output ports may operate at any signal frequency. The signal frequency may include relatively low frequencies, such as between 50 kHz and 300 kHz, as well as higher frequencies, such as frequencies of between about 60 MHz and about 100 MHz, virtually without limitation.

Particular embodiments described herein may show and/or describe multi-station semiconductor fabrication chambers comprising 4 process stations. However, the disclosed embodiments are intended to embrace multi-station integrated circuit fabrication chambers comprising any number of process stations. Thus, in certain implementations, an output signal of a RF power generator may be divided among, 2 process stations or 3 process stations of a fabrication chamber. An output power signal from a RF power generator may be divided among a larger number of process stations virtually without limitation, such as 5 process stations, 6 process stations, 8 process stations, 10 process stations. Particular embodiments described herein may show and/or describe utilization of a single, relatively low frequency RF signal, such as a frequency of between about 300 kHz and about 2 MHz, as well as a single, relatively high-frequency RF signal, such as a frequency of between 2 MHz and 100 MHz. The disclosed embodiments are intended to embrace the use of any number of radio frequencies, such as frequencies below 2 MHz, as well as any number of radio frequencies above 2 MHz.

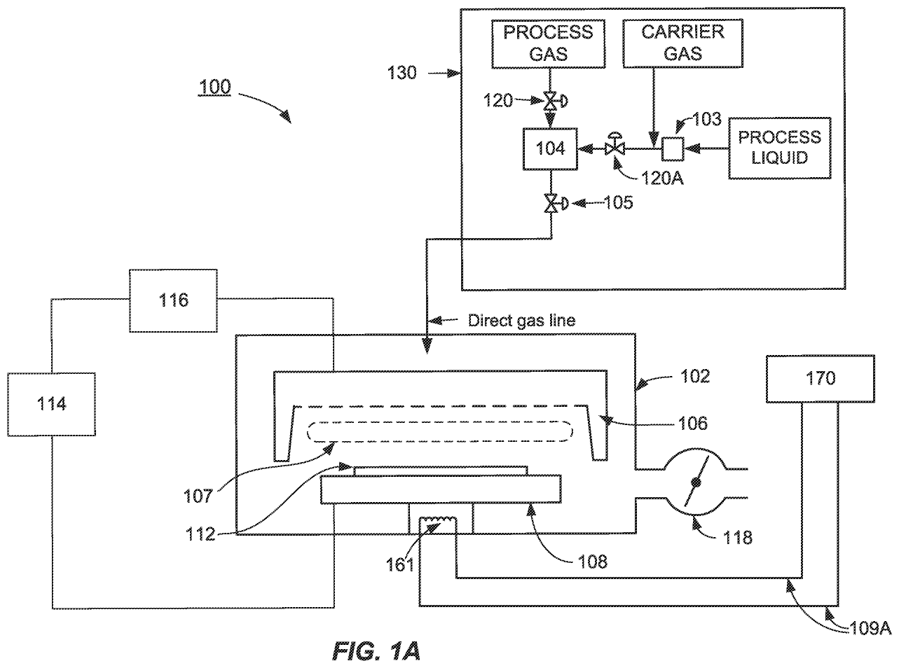

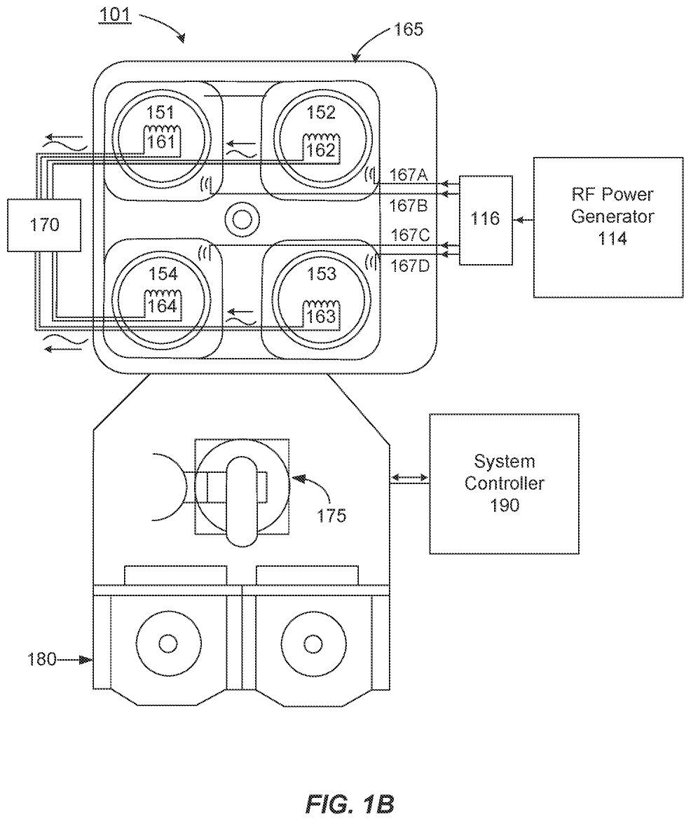

Manufacture of semiconductor devices may involve depositing or etching of one or more thin films on or over a planar or non-planar substrate in an integrated fabrication process. In some aspects of an integrated circuit fabrication process, it may be useful to deposit thin films that conform to unique substrate topography. One type of reaction that is useful in many instances may involve chemical vapor deposition (CVD). In certain CVD processes, gas phase reactants introduced into stations of a reaction chamber simultaneously undergo a gas-phase reaction. The products of the gas-phase reaction deposit on the surface of the substrate. A reaction of this type may be driven by, or enhanced by, presence of a plasma, in which case the process may be referred to as a plasma-enhanced chemical vapor deposition (PECVD) reaction. As used herein, the term CVD is intended to include PECVD unless otherwise indicated. CVD processes have certain disadvantages that render them less appropriate in some contexts. For instance, mass transport limitations of CVD gas phase reactions may bring about deposition effects that exhibit thicker deposition at top surfaces (e.g., top surfaces of gate stacks) and thinner deposition at recessed surfaces (e.g., bottom corners of gate stacks). Further, in response to some semiconductor die having regions of differing device density, mass transport effects across the substrate surface may result in within-die and within-wafer thickness variations. Thus, during subsequent etching processes, thickness variations can result in over-etching of some regions and under-etching of other regions, which can degrade device performance and die yield. Another difficulty related to CVD processes is that such processes are often unable to deposit conformal films in high aspect ratio features. This issue can be increasingly problematic as device dimensions continue to shrink. These and other drawbacks of particular aspects of wafer fabrication processes are discussed in relation to FIG. 1A and FIG. 1B.

In another example, some deposition processes involve multiple film deposition cycles, each producing a discrete film thickness. For example, in atomic layer deposition (ALD), thickness of a deposited layer may be limited by an amount of one or more film precursor reactants, which may adsorb onto a substrate surface, so as to form an adsorption-limited layer, prior to the film-forming chemical reaction itself. Thus, a feature of ALD involves the formation of thin layers of film, such as layers having a width of a single atom or molecule, which are used in a repeating and sequential matter. As device and feature sizes continue to be reduced in scale, and as three-dimensional devices and structures become more prevalent in integrated circuit (IC) design, the capability of depositing thin conformal films (e.g., films of material having a uniform thickness relative to the shape of the underlying structure) continues to gain in importance. Thus, in view of ALD being a film-forming technique in which each deposition cycle operates to deposit a single atomic or molecular layer of material, ALD may be well-suited to the deposition of conformal films. In some instances, device fabrication processes involving ALD may include multiple ALD cycles, which may number into the hundreds or thousands. Multiple ALD cycles may be utilized to form films of virtually any desired thickness. Further, in view of each layer being thin and conformal, a film that results from such a process may conform to a shape of any underlying device structure. In certain implementations, an ALD cycle may include the following steps:

Exposure of the substrate surface to a first precursor.

Purge of the reaction chamber in which the substrate is located.

Activation of a reaction of the substrate surface, such as by exposing the substrate surface with a plasma and/or a second precursor.

Purge of the reaction chamber in which the substrate is located.

The duration of each ALD cycle may, at least in particular embodiments, be less than about 25 seconds or less than about 10 seconds or less than about 5 seconds. The plasma exposure step (or steps) of the ALD cycle may be of a short duration, such as a duration of about 1 second or less.

Turning now to the figures, FIG. 1A shows an example apparatus for depositing or etching a film on or over a substrate utilizing any number of processes, according to various embodiments. Processing apparatus 100 of FIG. 1A depicts single process station 102 of a process chamber with a single substrate holder 108 (e.g., a pedestal) in an interior volume, which may be maintained under vacuum by vacuum pump 118. Showerhead 106 and gas delivery system 130 may be fluidically coupled to the process chamber. Showerhead 106 and gas delivery system 130 may permit the delivery of film precursors, carrier and/or purge and/or process gases, secondary reactants, etc. Equipment utilized in the generation of plasma within the process chamber is also shown in FIG. 1A. The apparatus schematically illustrated in FIG. 1A may be adapted for performing, in particular, plasma-enhanced CVD.

In FIG. 1A, gas delivery system 130 includes a mixing vessel 104 for blending and/or conditioning process gases for delivery to showerhead 106. One or more mixing vessel inlet valves 120 may control introduction of process gases to mixing vessel 104. Particular reactants may be stored in liquid form prior to vaporization and subsequent delivery to process station 102 of a process chamber. The embodiment of FIG. 1A includes a vaporization point 103 for vaporizing liquid reactant to be supplied to mixing vessel 104. In some implementations, vaporization point 103 may include a heated liquid injection module. In some other implementations, vaporization point 103 may include a heated vaporizer. In yet other implementations, vaporization point 103 may be eliminated from the process station. In some implementations, a liquid flow controller (LFC) upstream of vaporization point 103 may be provided for controlling a mass flow of liquid for vaporization and delivery to process station 102.

Showerhead 106 may operate to distribute process gases and/or reactants (e.g., film precursors) toward substrate 112 at the process station, the flow of which may be controlled by one or more valves upstream from the showerhead (e.g., valves 120, 120A, 105). In the embodiment depicted in FIG. 1A, substrate 112 is depicted as located beneath showerhead 106, and is shown resting on a pedestal 108. Showerhead 106 may be of any suitable shape, and may include any suitable number and arrangement of ports for distributing process gases to substrate 112. In some implementations involving 2 or more stations, gas delivery system 130 includes valves or other flow control structures upstream from the showerhead, which can independently control the flow of process gases and/or reactants to each station so as to permit gas flow to one station while prohibiting gas flow to a second station. Furthermore, gas delivery system 130 may be configured to independently control process gases and/or reactants delivered to each station in a multi-station apparatus such that the gas composition provided to different stations is different (e.g., the partial pressure of a gas component may vary between stations at the same time).

In FIG. 1A, volume 107 is depicted as being located beneath showerhead 106. In some implementations, pedestal 108 may be raised or lowered to expose substrate 112 to volume 107 and/or to vary the size of volume 107. Optionally, pedestal 108 may be lowered and/or raised during portions of the deposition process to modulate process pressure, reactant concentration, etc., within volume 107. Showerhead 106 and pedestal 108 are depicted as being electrically coupled to RF power generator 114 and matching network 116 for providing a signal to a plasma-generating structure. Thus, in certain implementations, showerhead 106 may function as an electrode for coupling RF power into process station 102. In some implementations, the plasma energy is controlled (e.g., via a system controller having appropriate machine-readable instructions and/or control logic) by controlling one or more of a process station pressure, a gas concentration, power generated by a RF power generator, and so forth. For example, RF power generator 114 and matching network 116 may be operated at any suitable RF power level, which may operate to bring about formation of a plasma having a desired composition of radical gaseous species. In addition, RF power generator 114 may provide RF power having more than one frequency component, such as a low-frequency component (e.g., less than 2 MHz) as well as a high frequency component (e.g., greater than 2 MHz).

In the embodiment of FIG. 1A, active element 161 may be placed beneath pedestal 108. Active element 161 may be utilized to bring about heating of pedestal 108 as well as substrate 112. In some implementations, active element 161 may correspond to a resistive heating coil. In certain implementations, showerhead 106 and active element 161 may cooperate to enhance formation of plasma. Enhanced formation of plasma may, consequently, accelerate material deposition and/or material removal (e.g., etching) processes occurring within process station 102. Current generator 170 is shown as supplying an electrical current, by way of conductors 109A, to active element 161.

In some implementations, plasma generation and maintenance conditions are controlled via appropriate hardware and/or appropriate machine-readable instructions accessible to a system controller. Machine-readable instructions may include a non-transitory sequence of input/output control (IOC) instructions encoded on a computer-readable media. In one example, the instructions for generating or maintaining a plasma are provided in the form of a plasma activation recipe of a process recipe. In some cases, process recipes may be sequentially arranged, so that at least some instructions for the process can be executed concurrently. In some implementations, instructions for setting one or more plasma parameters may be included in a recipe preceding a plasma generation process. For example, a first recipe may include instructions for setting a flow rate of an inert (e.g., helium) and/or a reactant gas, instructions for setting a plasma generator to a power set point and time delay instructions for the first recipe. A second, subsequent recipe may include instructions for enabling the plasma generator and time delay instructions for the second recipe. A third recipe may include instructions for disabling the plasma generator and time delay instructions for the third recipe. It will be appreciated that these recipes may be further subdivided and/or iterated in any suitable way within the scope of the present disclosure. In some deposition processes, a duration of a plasma strike may correspond to a duration of a few seconds, such as from about 3 seconds to about 15 seconds, or may involve longer durations, such as durations of up to about 30 seconds, for example. In certain implementations described herein, much shorter plasma strikes may be applied during a processing cycle. Such plasma strike durations may be on the order of less than about 50 milliseconds, with about 25 milliseconds being utilized in a specific example.

For simplicity, processing apparatus 100 is depicted in FIG. 1A as a standalone station (102) of a process chamber for maintaining a low-pressure environment. However, it may be appreciated that a plurality of process stations may be included in a multi-station processing tool environment, such as shown in FIG. 1B, which depicts a schematic view of an example multi-station processing tool, according to various embodiments. Processing tool 101 employs an integrated circuit fabrication chamber 165 that includes multiple process stations. Process stations may be utilized to perform processing operations on a substrate retained via a wafer holder, such as pedestal 108 of FIG. 1A, at a particular process station. In the example of FIG. 1B, integrated circuit fabrication chamber 165 is shown as comprising 4 process stations 151, 152, 153, and 154. Other similar multi-station processing apparatuses may include more or fewer process stations depending on the implementation and, for instance, the desired level of parallel wafer processing, size/space constraints, cost constraints, etc. Also shown in FIG. 1B is substrate handler robot 175, which can operate under the control of system controller 190. Substrate handler robot 175 can be configured or adapted to move substrates from a wafer cassette (not shown in FIG. 1B). Substrates from a wafer cassette may be moved from loading port 180 and into multi-station integrated circuit fabrication chamber 165 and onto one of process stations 151, 152, 153, and 154.

FIG. 1B also depicts an embodiment of a system controller 190 employed to control process conditions and hardware states of processing tool 101. System controller 190 may include one or more memory devices, one or more mass storage devices, and one or more processors. The one or more processors may include a central processing unit, analog and/or digital input/output connections, stepper motor controller boards, etc. In some implementations, system controller 190 controls all of the activities of process tool 101. System controller 190 executes system control software stored in a mass storage device, which may be loaded into a memory device, and executed by a processor of the system controller. Software to be executed by a processor of system controller 190 may include instructions for controlling the timing, mixture of gases, fabrication chamber and/or station pressure, fabrication chamber and/or station temperature, wafer temperature, substrate pedestal, chuck and/or susceptor position, number of cycles performed on one or more substrates, and other parameters of a particular process performed by process tool 101. These programed processes may include various types of processes including, but not limited to, processes related to determining an amount of accumulation on a surface of the chamber interior, processes related to deposition of film on substrates including numbers of cycles, determining and obtaining a number of compensated cycles, and processes related to cleaning the chamber. System control software, which may be executed by one or more processors of system controller 190, may be configured in any suitable way. For example, various process tool component subroutines or control objects may be written to control operation of the process tool components necessary to carry out various tool processes.

In some embodiments, software for execution by way of a processor of system controller 190 may include input/output control (IOC) sequencing instructions for controlling the various parameters described above. For example, each phase of deposition and deposition cycling of a substrate may include one or more instructions for execution by system controller 190. The instructions for setting process conditions for an ALD conformal film deposition process phase may be included in a corresponding ALD conformal film deposition recipe phase. In some implementations, the recipe phases may be sequentially arranged, so that all instructions for a process phase are executed concurrently with that process phase.

Other computer software and/or programs stored on a mass storage device of system controller 190 and/or a memory device accessible to system controller 190 may be employed in some embodiments. Examples of programs or sections of programs for this purpose include a substrate positioning program, a process gas control program, a pressure control program, a heater control program, and a plasma control program. A substrate positioning program may include program code for process tool components that are used to load the substrate onto pedestal 108 (of FIG. 1A) and to control the spacing between the substrate and other parts of process tool 101. A positioning program may include instructions for appropriately moving substrates in and out of the reaction chamber as necessary to deposit films on substrates and to clean the chamber.

A process gas control program may include code for controlling gas composition and flow rates and for controlling the flow of gas into one or more process stations prior to deposition, which may bring about stabilization of the pressure in the process station. In some embodiments, the process gas control program includes instructions for introducing gases during formation of a film on a substrate in the reaction chamber. This may include introducing gases for a different number of cycles for one or more substrates within a batch of substrates. A pressure control program may include code for controlling the pressure in the process station by regulating, for example, a throttle valve in an exhaust system of the process station, a gas flow into the process station, etc. The pressure control program may include instructions for maintaining the same pressure during the deposition of a differing number of cycles on one or more substrates during the processing of the batch.

A heater control program may include code for controlling the current to current generator 170 that is used to heat the substrate. Thus, in particular embodiments, current generator 170 may correspond to a voltage source, such as a voltage source to supply a direct current or an alternating current. In certain embodiments, current generator 170 may correspond to a current generator, such as a current source to generate a direct current or an alternating current. In either embodiment, however, it is contemplated that current generator 170 is capable of supplying sufficient voltage and/or sufficient current to bring about a measurable change in temperature of one or more gases present in all of process stations 151, 152, 153, and 154. Such change in temperature may operate to bring about or enhance a plasma generation process, in which ionized gaseous components operate to deposit material on a substrate or to etch material from a substrate. In the embodiment of FIG. 1B, current generator 170 supplies current to active elements 161, 162, 163, and 164. However, in other embodiments, current generator 170 may supply current to a different number of heating elements, such as fewer than 4 active elements. In other embodiments, current generator 170 may supply current to a greater number of heating elements such as 5 active elements, 6 active elements, 8 active elements, 10 active elements, and so forth, virtually without limitation.

System controller 190 may additionally control and/or manage the operations of RF power generator 114, which may generate and transmit RF power to multi-station integrated circuit fabrication chamber 165 via RF power input ports 167A, 167B, 167C, and 167D. Such operations may relate to determining upper and lower thresholds for RF power to be delivered to integrated circuit fabrication chamber 165, RF power activation/deactivation times, RF power on/off duration, duty cycle, operating frequencies, and so forth. Additionally, system controller 190 may determine a set of normal operating parameters of RF power to be delivered to integrated circuit fabrication chamber 165 by way of RF power input ports 167A, 167B, 167C, and 167D. Such parameters may include upper and lower thresholds of, for example, power reflected from RF power input ports 167A, 167B, 167C, and 167D in terms of a reflection coefficient (e.g., the scattering parameter S₁₁) or a voltage standing wave ratio. Such parameters may also include upper and lower thresholds of a voltage applied to RF power input port 167A-167D, upper and lower thresholds of current conducted through RF power input ports 167A, 167B, 167C, and 167D, as well as an upper threshold for a magnitude of a phase angle between a voltage and a current conducted through RF power input ports 167A, 167B, 167C, and 167D. Such thresholds may be utilized in defining “out-of-range” RF signal characteristics. For example, reflected power greater than an upper threshold may indicate an out-of-range RF power parameter. Likewise, an applied voltage or conducted current having a value below a lower threshold or greater than an upper threshold may indicate out-of-range RF signal characteristics.

In certain implementations, RF power generator 114 may operate to generate two frequencies, such as a first frequency of about 400 kHz and a second frequency of about 27.12 MHz. It should be noted, however, that RF power generator may be capable of generating additional frequencies, such as frequencies of between about 300 kHz and about 100 MHz, and implementations are not limited in this respect. In particular embodiments, signals generated by RF power generator 114 may include at least one low frequency (LF), which may be defined as a frequency of between about 300 kHz and about 2 MHz, and at least one high frequency (HF), which may be defined as a frequency greater than about 2 MHz but less than about 100 MHz.

In particular embodiments, multi-station integrated circuit fabrication chamber 165 may include input ports in addition to input ports 167A-167D. In certain embodiments, each process station of integrated circuit fabrication chamber 165 may utilize first and second input ports, in which a first input port may be utilized to convey a signal having a first frequency and in which a second input port may convey a signal having a second frequency. Use of 2 or more frequencies may bring about enhanced plasma characteristics, which may give rise to deposition rates or etch rates within particular limits and/or more easily controlled deposition/etch rates. Use of 2 or more frequencies may bring about other desirable consequences, and the disclosed implementations are not limited to these frequencies.

In some embodiments, there may be a user interface associated with system controller 190. The user interface may include a display screen, graphical software displays of the processing tool and/or process conditions, and user input devices such as pointing devices, keyboards, touch screens, microphones, etc.

In some embodiments, parameters adjusted by system controller 190 may relate to process conditions. Non-limiting examples may include process gas composition and flow rates, temperature, pressure, plasma conditions, etc. These parameters may be provided to the user in the form of a recipe. The recipe may be entered utilizing a user interface. The recipe for an entire batch of substrates may include compensated cycle counts for one or more substrates within the batch in order to account for thickness trending over the course of processing the batch.

Signals for monitoring a fabrication process may be provided by analog and/or digital input connections of system controller 190 from various process tool sensors. Signals for controlling the process may be transmitted by way of the analog and/or digital output connections of process tool 101. Non-limiting examples of process tool sensors that may be monitored include mass flow controllers, pressure sensors (such as manometers), thermocouples, etc. Sensors may also be included and used to monitor and determine the accumulation on one or more surfaces of the interior of the chamber and/or the thickness of a material layer on a substrate in the chamber. Appropriately programmed feedback and control algorithms may be used with data from these sensors to maintain process conditions.

System controller 190 may provide program instructions for implementing the above-described deposition processes. The program instructions may control a variety of process parameters, such as DC power level, pressure, temperature, number of cycles for a substrate, amount of accumulation on at least one surface of the chamber interior, etc. The instructions may control the parameters to operate in-situ deposition of film stacks according to in embodiment described herein.

For example, the system controller may include control logic for performing the techniques described herein, such as determining (a) an amount of accumulated deposition material currently on at least an interior region of the deposition chamber interior. In addition, the system controller may include control logic for applying the amount of accumulated deposition material determined in (a), or a parameter derived therefrom, to a relationship between (i) a number of ALD cycles required to achieve a target deposition thickness, and (ii) a variable representing an amount of accumulated deposition material, in order to obtain a compensated number of ALD cycles for producing the target deposition thickness given the amount of accumulated deposition material currently on the interior region of the deposition chamber. The system controller may include control logic for performing the compensated number of ALD cycles on one or more substrates in the batch of substrates. The system may also include control logic for determining that the accumulation in the chamber has reached an accumulation limit and stopping the processing of the batch of substrates in response to that determination, and for initiating a cleaning operation of the chamber interior.

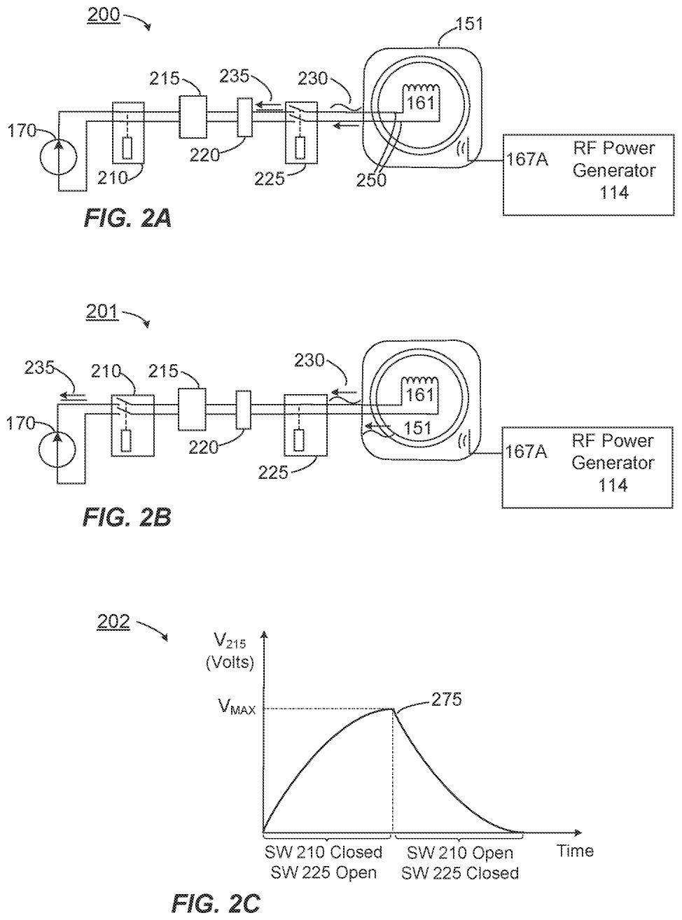

In particular embodiments, it may be desirable for maximum power to be coupled from RF power generator 114 to input ports 167A-167D of multi-station integrated circuit fabrication chamber 165. Thus, to bring about maximum power coupling from RF power generator 114, parasitic losses introduced by the coupling of RF signals to locations outside of multi-station integrated circuit fabrication chamber 165 may be reduced. FIG. 2A is a schematic diagram showing the states of one or more first switches in an example apparatus that operates to decouple RF signals from input signal conductors of a process station of a multi-station integrated circuit fabrication chamber, according to an embodiment 200. Although FIG. 2A indicates only a single process station (151), at least in particular embodiments, an apparatus similar to that of FIG. 2A may be utilized in association with additional process stations (e.g., 152, 153, and 154) of a multi-station integrated circuit fabrication chamber.

In FIG. 2A, current generator 170 represents any type of alternating current or direct current generator. In particular embodiments, current generator 170 is configured to generate a predefined current, in which amplitude of an output voltage may vary. In other embodiments, current generator 170 generates a predefined voltage, in which amplitude of an output current may vary. It should be noted that the disclosed embodiments are intended to embrace all types of voltage and current generators operating to produce an alternating current or a direct current. It may be appreciated that responsive to closing of switches 210 and 225, current may be permitted to conduct from current generator 170, through energy storage device 215, and through RF filter 220. Upon reaching active element 161 within process station 151, the conducted current may bring about resistive heating within process station 151. In other embodiments, current conducted from current generator 170 may be coupled to additional active elements, such as ultraviolet light sources, infrared heat sources, etc., and the disclosed embodiments are intended to embrace any such active elements utilized to impart energy into a process station of a fabrication chamber.

It may also be appreciated that as a consequence of the closing of switches 210 and 225, an amount of RF energy may be parasitically coupled to conductors of active element 161. Thus, as shown in FIG. 2A, RF energy from input port 167A may be radiated to (or conducted by) conductors 250. Also as shown in FIG. 2A, sinusoidal waveform 230 may propagate in the direction of current generator 170. In certain embodiments, such parasitic coupling may represent a percentage (e.g., about 1%, or about 2%, or about 5%) of RF signal power coupled to a station via input port 167A. It may be appreciated that such parasitic losses do not contribute or assist in an integrated circuit fabrication process. Rather, such parasitic coupling represents unproductive RF power. Further, such parasitic coupling can represent an additional load that may fluctuate as a function of time. These fluctuations in the load presented by the combination of process station 151 and parasitic couplings may adversely affect impedance matching between RF power generator 114 and RF input power port 167A. Additionally, such parasitic signals may radiate and/or conduct RF energy that may interfere with sensitive electronic circuitry located or electrically connected along the path between current generator 170 and process station 151.

Thus, to preclude parasitic coupling of RF energy from process station 151, switching states of switch 225 and switch 210 may be adjusted to open a circuit path between active element 161 and current generator 170. In the embodiment of FIG. 2A, switch 225 may be occasionally or periodically opened, which may prevent conduction of RF signal current from process station 151 towards current generator 170. While switch 225 is open, sinusoidal waveform 230 is not permitted to pass between process station 151 and current generator 170. Thus, as shown in FIG. 2A, responsive to the opening of switch 225, sinusoidal waveform 230 is reduced in amplitude, as represented by quiescent waveform 235. In particular embodiments, switch 225 may be located proximate with process station 151, so as to limit a physical distance traversed by sinusoidal waveform 230 prior to being extinguished by switch 225. In certain embodiments, by way of limiting a physical distance between switch 225 and process station 151, conductor lengths, such as lengths of conductors 250, may be kept correspondingly small. By way of constraining conductors 250 to relatively small lengths, at least in comparison to the wavelength of a RF signal generated by RF power generator 114, conductors 250 may be prevented from behaving as an antenna. Thus, in certain embodiments, the length of conductor 250 (e.g., between process station 151 and switch 225) may be kept to a value of less than λ/10, where λ corresponds to the wavelength of the highest frequency signal generated by RF power generator 114.

In the embodiment of FIG. 2A, while switch 225 is open, second switch 210 may be closed. Closure of switch 210 permits current generator 215 to apply charge to energy storage device 215. Energy storage device 215 may represent a capacitive device, which may store energy in the form of electrical charges. Alternatively, energy storage device 215 may represent an inductive device, which may store energy in the form of an electric current. Energy storage device 215 may operate to store energy utilizing other phenomena, such as energy storage via a reversible chemical reaction. It should be noted that the disclosed embodiments are intended to embrace all devices capable of energy storage.

FIG. 2B is a schematic diagram showing second switch states of the example apparatus shown in FIG. 2A, according to an embodiment 201. In FIG. 2B, in response to energy storage device 215 being fully (or at least significantly) charged, switch 210 may be opened thereby interrupting a flow of charge from current generator 170. Following opening of switch 210, switch 225 may be closed. Such closure of switch 225 may permit a current to be conducted from energy storage device 215 to active element 161. In addition, in response to switch 210 being opened, parasitic RF signals may be prevented from conducting from active element 161 toward current generator 170.

Returning briefly to the embodiment of FIG. 2A, RF filter 220 may operate to provide filtering (or attenuating) of RF signals that may be present in response to RF signal conduction through the case or enclosure of second switch 225 or through any other signal path. In particular embodiments, RF filter 220 may operate as a low-pass filter, which may block or significantly attenuate frequencies generated by RF power generator 114. Thus, in an example, when RF power generator 114 generates a composite signal of about 400 kHz and about 27.12 MHz, RF filter 220 may be designed to reject these frequencies. In an example embodiment, RF filter 220 may be designed or configured to pass frequencies below 100 kHz, and to attenuate frequencies above 100 kHz. Accordingly, only negligible amounts of RF energy generated by RF power generator 114 (e.g., 400 kHz, 13.56 MHz, 27.12 MHz) are permitted to pass from process station 151 through RF filter 220. In particular embodiments, RF filter 220 may attenuate frequencies above 100 kHz by at least 20 dB, although the disclosed embodiments are intended to embrace low-pass filters that attenuate signals by different amounts, such as 25 dB, 30 dB, 35 dB, 40 dB, and so forth, virtually without limitation.

FIG. 2C shows an example waveform (275) depicting charging and discharging of the energy storage device of FIGS. 2A and 2B, according to an embodiment 202. As shown in the first portion of FIG. 2C, responsive to first switch 225 being open and switch 210 being closed, energy storage device 215 may charge. Thus, for example, if energy storage device 215 corresponds to a capacitor, the voltage across device 215 charges substantially in accordance with expression (1) below:

$${V}_{215} = {V}_{170} ( 1 - {e}^{( - \frac{t}{RC} )} ) \qquad ( 1 )$$

In expression (1), V₁₇₀ corresponds to a voltage produced by current generator 170, C corresponds to capacitance of energy storage device 215, and R corresponds to resistance presented by one or more resistive heating elements of active element 161. Thus, as shown in FIG. 2C, in response to switch 210 being closed and switch 225 being open, energy storage device 215 is shown as being charged. In response to switch 210 being opened, thereby interrupting charge flow from current generator 170, energy storage device 215 is shown as being discharged. It should be noted that although FIG. 2C indicates complete (or near-complete) charging and discharging of energy storage device 215, in certain embodiments, an energy storage device may be only partially charged/discharged. To control an amount of charging/discharging of energy storage devices, the periods during which switches 210/225 remain open/closed may be adjusted.

It should be noted that waveform 275 of FIG. 2C represents a voltage profile that may be observed if energy storage device 215 corresponds to a capacitor and if current generator 170 generates a voltage of V_{MAX}. However, responsive to energy storage device 215 corresponding to a different type of energy storage device (e.g., inductor, battery, etc.) waveform 275 may reflect a different charging/discharging profile, and the disclosed embodiments are not limited in this respect. It should also be noted that if energy storage device 215 comprises a capacitor, selection of a capacitance value may depend on a number of factors. These factors may include the amount of energy (e.g., in Joules) to be stored by energy storage device 215, the rate at which switches 210/215 switch, current draw of active element 161, and so forth. In particular embodiments, energy storage device 215 comprises a capacitor having a value of between about 1 mF to about 100 mF. In certain embodiments, energy storage device 215 comprises an inductor having a value of between about 1 mH to about 100 mH. In certain other embodiments, energy storage device comprises a battery configured for storage of between about 1 Joule (1 Watt-second) and 100 Joule (100 Watt-second).

In certain other embodiments, energy storage device 215 may include a capability to provide sufficient energy to drive a plurality of active elements 161 for, perhaps, 10-15 minutes. Thus, in an example, if an active element delivers 2 kW, utilizing an approximately 50% duty cycle, then 4 active elements (e.g., 1 active element for each of process stations 151-154 of FIG. 1B) consumes 4 kW (2 kW×0.5×4 process stations). In addition, if each active element provides power during an approximately 10-minute duration per hour, then an energy storage device may store, for example, 0.667 kWh (4 process stations×10/60). In other embodiments, which may utilize active elements consuming different amounts of input power, utilizing duty cycles other than 50%, an energy storage device may include a capability to store between 0.2 kWh and 1.5 kWh.

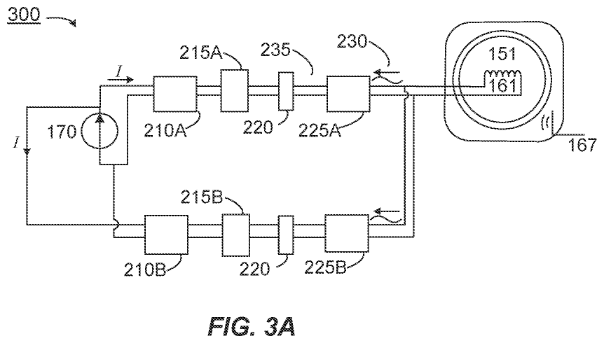

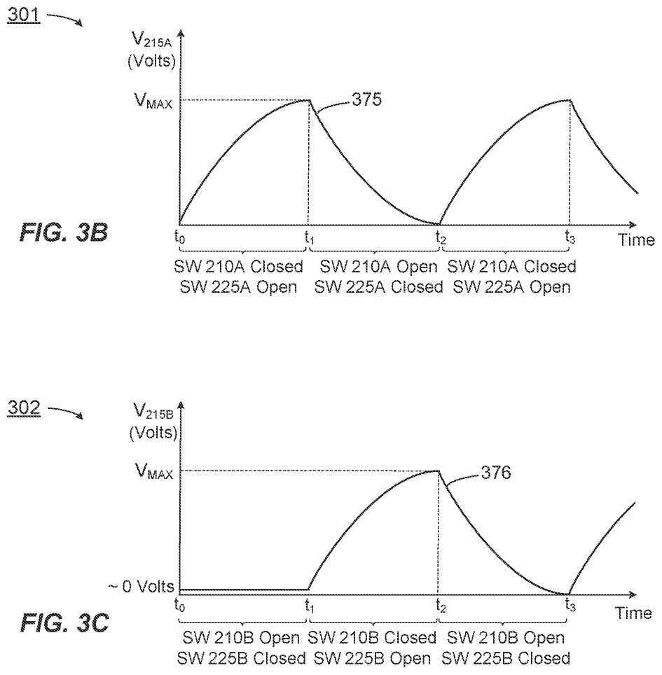

It may be appreciated that during discharging of energy storage device 215 (e.g., while switch 210 is maintained in an open position) little or no current may flow from current generator 170. Accordingly, in such instances, current generator 170 may be idled until switch 210 is again closed and switch 225 is opened. Thus, FIG. 3A is a schematic diagram showing energy storage devices arranged in parallel in an apparatus to decouple RF signals from input signal conductors of a process station, according to an embodiment 300. In FIG. 3A, the parallel arrangement of energy storage devices, along with RF filters and first and second switches arranged in series with each energy storage device, permits a first energy storage device (e.g., 215A) to be charged while a second energy storage device (e.g., 215B) is being discharged. It may be appreciated that as a consequence of such an arrangement, current generator 170 is seldom (or perhaps never) operating in an idle state.

For example, during a first time period, switch 210A may be closed while switch 225A is opened, thereby permitting current generator 170 to charge energy storage device 215A without permitting current to conduct to active element 161. Responsive to energy storage device 215A charging to a predetermined level, switch 225A may be closed and switch 210A may be opened, thereby permitting charge to conduct from energy storage device 215A to active element 161. In addition, while charge is conducted from energy storage device 215A to active element 161, switch 225B may be opened, and switch 210B may be closed. Closing of switch 210B may permit charge to conduct from current generator 170 to energy storage device 215B until, for example, energy storage device 215B charges to a predetermined level. Responsive to energy storage device 215B charging to a predetermined level, switch 225B may be closed and switch 210B may be opened, thereby permitting charge to conduct from energy storage device 215B to active element 161. While charge conducts from energy storage device 215B to active element 161, switch 225A may be opened, and switch 210A may be closed, thereby permitting charge to again flow from current generator 170 to energy storage device 215A.

Thus, the embodiment depicted in FIG. 3A permits current generator 170 to provide an electric current to a first energy storage device while a second energy storage device is being discharged. Responsive to charging of the first energy storage device and discharging of the second energy storage device, the first energy storage device may be discharged while the second energy storage device is charged. Thus, the first and second energy storage devices may be alternately charged and discharged in a manner that maintains current generator 170 in an active (current-supplying) state at substantially all times.

FIGS. 3B (embodiment 301) and 3C (embodiment 302) show example waveforms depicting charging and discharging of the parallel-connected energy storage devices of FIG. 3A. FIG. 3B (waveform 375) depicts a voltage measured at energy storage device 215A, and FIG. 3C (waveform 376) depicts a voltage measured at energy storage device 215B. Referring to FIG. 3B, at time t₀, switch 210A is closed and switch 225A is open, thereby permitting charge to accumulate at energy storage device 215A. At time t₁, switch 210A is opened and switch 225A is closed, thereby interrupting charge accumulation at energy storage device 215A and enabling discharge of device 215B from a voltage corresponding to V_{MAX} to a value that approaches 0 V. At time t₂, switch 210A is again closed and switch 225A is opened, thus permitting charge to re-accumulate at energy storage device 215A so as to attain a voltage of V_{MAX}. At time t₃, switch 210A may again be opened and switch 225A may be closed, thereby permitting energy storage device 215A to discharge from V_{MAX}.

Referring now to FIG. 3C, while switch 210A is closed and switch 225A is opened, such as between at time t₀ and t₁, a voltage measured at energy storage device 215B is maintained at an initial state (e.g., about 0 Volt). At t₁, while switch 210A is open and switch 225A is closed, switch 210B may be closed and switch 225B may be opened, thereby permitting charge to accumulate at energy storage device 215B. It may be appreciated that while energy storage device 215A is permitted to discharge, as shown by waveform 375, energy storage device 215B is permitted to charge, as shown by waveform 376. Such a complementary arrangement permits current generator 170 to remain in a current-supplying state at substantially all times.

It should be noted that although FIGS. 3A-3C refer to a parallel combination of 2 energy storage devices (e.g., 215A and 215B), in other embodiments, a greater number of energy storage devices may be utilized. Thus, in particular embodiments, a parallel combination of 3, 4, or 5 energy storage devices may be utilized. In still other embodiments, an even larger number of energy storage devices may be utilized, such as 6 energy storage devices, 8 energy storage devices, and so forth, virtually without limitation. It should also be noted that the switch-closed/switch-open durations depicted in FIGS. 3B-3C (e.g., t₀-t₁, t₁-t₂, and so forth) may correspond to durations of, for example, between about 10 ms and about 10 minutes. It should be noted that although FIGS. 3B/3C indicate complete (or near-complete) charging and discharging of an energy storage device, in certain embodiments, an energy storage device may be only partially charged/discharged. To control an amount of charging/discharging of energy storage devices, the periods during which switches 210λ/225A and 210B/225B remain open/closed may be adjusted.

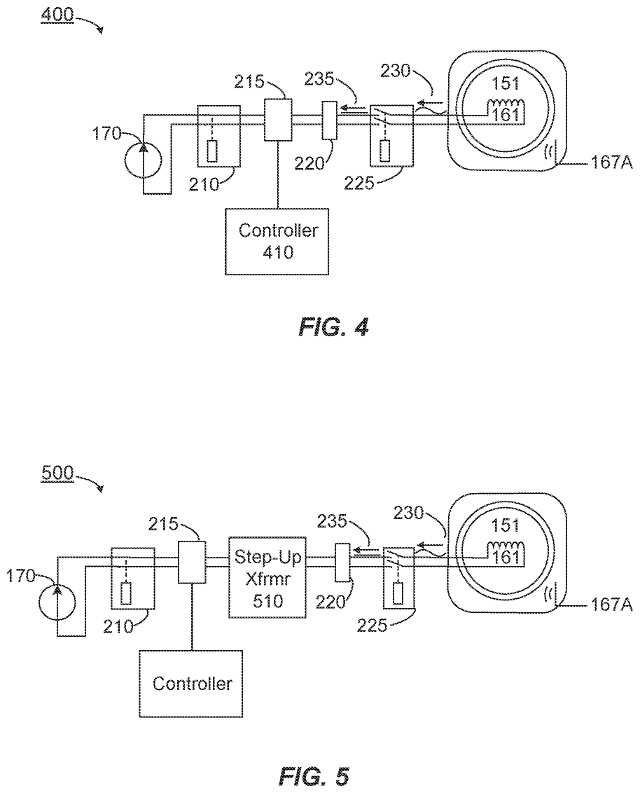

FIG. 4 is a schematic diagram showing a controller coupled to an energy storage device in an example apparatus to decouple RF signals from input signal conductors of a process station, according to an embodiment 400. In the embodiment of FIG. 4, controller 410 may operate to modify (e.g., increase or decrease) energy storage capability of energy storage device 215. Thus, in an example, if energy storage device 215 corresponds to a capacitor having one or more parallel plates, controller 410 may operate to move one or more plates in between other plates of the parallel plate capacitor. In another embodiment involving the use of a capacitive element for energy storage device 215, controller 410 may operate to switch additional capacitive elements in parallel with other capacitive elements, so as to increase capacitance of energy storage device 215. In particular embodiments, such switching of capacitive elements may adjust an energy storage capability of a capacitive device substantially in accordance with expression (2), below:

E=½CV² (2)

Expression 2 relates energy stored (E) by a capacitor as the product of capacitance (C) multiplied by an applied voltage (V).

In another embodiment, if energy storage device 215 comprises one or more inductive elements, controller 410 may operate to switch additional inductive elements in series with other inductive elements, so as to increase the overall inductance of energy storage device 215. In an embodiment, such switching of inductive elements may adjust an energy storage capability of an inductive device substantially in accordance with expression (3), below:

E=½LI² (3)

Expression 3 relates energy stored (E) by an inductor as the product of inductance (L) multiplied by a current conducted through the inductor (I). In other embodiments, controller 410 may operate to adjust capacity of a chemical storage device (e.g., a battery), such as by electrically connecting additional chemical storage elements to energy storage device 215.

FIG. 5 is a schematic diagram showing a step-up transformer coupled to an energy storage device in an example apparatus to decouple RF signals from input signal conductors of a process station, according to an embodiment 500. In the embodiment of FIG. 5, step up transformer 510 may operate to increase in output voltage from energy storage device 215 to a rated voltage of active element 161.

It should be noted that differing arrangements of energy storage devices may be utilized at process stations of a multi-station integrated circuit fabrication chamber. For example, a parallel arrangement of energy storage devices, such as that shown in FIG. 3A, may be utilized to provide electric current to active element 161 of FIG. 1B. Meanwhile, a single energy storage device, such as shown in in FIG. 2A/2B may be utilized to provide an electrical current to active element 164 of FIG. 1B. In certain embodiments, determination of the number of energy storage devices to be utilized with a particular active element of an individual process station may be based, at least in part, on a desired charging/discharging rate, a duty cycle of an energy storage device, an energy storage device capacity, current requirements of an active element, and/or other constraints.

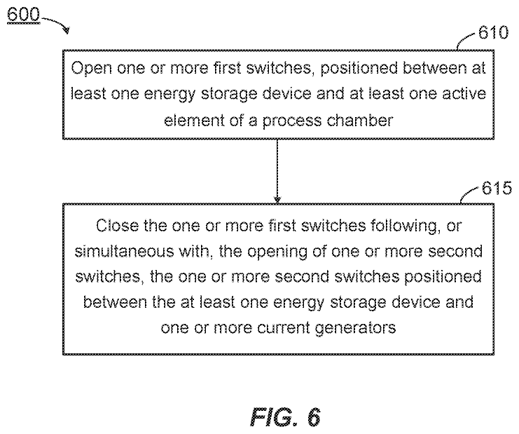

FIG. 6 is a flowchart for an example method of decoupling RF signals from input signal conductors of a process chamber, according to an embodiment 600. It should be noted that the disclosed embodiments are intended to embrace variations of FIG. 6, including methods that include actions in addition to those of FIG. 6, actions performed in an order different than those of FIG. 6, as well as methods including fewer steps than those shown in FIG. 6. In addition, although the apparatuses of FIGS. 1A, 1B, 2A, 2B, 3A, 4, and 5 are suitable for performing the method of FIG. 6, the method may be performed by other apparatuses, systems, or arrangements, and the disclosed embodiments are not limited in this respect. The method of FIG. 6 begins at 610, which includes opening of one or more first switches, wherein the one or more first switches are positioned between at least one energy storage device and at least one active element of a process chamber. In particular embodiments, opening of one or more first switches positioned between the at least one energy storage device and an active element of a process chamber may permit a current or voltage source to charge an energy storage device to a predetermined potential.

The method of FIG. 6 may continue at 615, which may include closing the one or more first switches following, or simultaneously with, the opening of the one or more second switches. The one or more second switches may be positioned between the at least one energy storage device and one or more current generators. In particular embodiments, 615 may permit discharge of an energy storage device to provide power to an active element of a process station of a multi-station integrated circuit fabrication chamber.

The method of FIG. 6 may involve use of a processor which, after a duration, directs opening of the one or more second switches and, following or simultaneously with the opening of the one or more second switches, initiates the closing of the one or more first switches. In one example, returning briefly to FIG. 2A, a processor (not shown) may direct the opening of switch 210 after a duration that permits charging of energy storage device 215 by current generator 170. Following or simultaneously with the opening of switch 210, the processor may initiate closing of switch 225 so as to permit current to flow from energy storage device to active element 161. The method of FIG. 6 may additionally include the processor additionally operating to modify a value of capacitance or inductance of an energy storage device. For example, returning briefly to FIG. 4, controller 410 may involve use of a processor to modify a value of a capacitance or inductance of energy storage device 215. The method of FIG. 6 may additionally include the processor additionally directing closing of one first switches responsive to an indication that at least one energy storage device has accumulated a predetermined threshold amount of energy. For example, returning briefly to FIG. 2, a processor (not shown in FIG. 2) may operate to open switch 210 responsive to detecting that energy storage device has attained the maximum voltage (V_{MAX}) and close switch 225, thereby permitting current to conduct from energy storage device 215 to active element 161.

Broadly speaking, controller 190 may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers or field-programmable gate arrays (FPGA) or FPGA with system-on-a-chip (SoC) that that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus, as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

In the foregoing detailed description, numerous specific details are set forth to provide a thorough understanding of the presented embodiments or implementations. The disclosed embodiments or implementations may be practiced without some or all of these specific details. In other instances, well-known process operations have not been described in detail so as to not unnecessarily obscure the disclosed embodiments or implementations. While the disclosed embodiments or implementations are described in conjunction with the specific embodiments or implementations, it will be understood that such description is not intended to limit the disclosed embodiments or implementations.

The foregoing detailed description is directed to certain embodiments or implementations for the purposes of describing the disclosed aspects. However, the teachings herein can be applied and implemented in a multitude of different ways. In the foregoing detailed description, references are made to the accompanying drawings. Although the disclosed embodiments or implementation are described in sufficient detail to enable one skilled in the art to practice the embodiments or implementation, it is to be understood that these examples are not limiting; other embodiments or implementation may be used and changes may be made to the disclosed embodiments or implementation without departing from their spirit and scope. Additionally, it should be understood that the conjunction “or” is intended herein in the inclusive sense where appropriate unless otherwise indicated; for example, the phrase “A, B, or C” is intended to include the possibilities of “A,” “B,” “C,” “A and B,” “B and C,” “A and C,” and “A, B, and C.”

In this application, the terms “semiconductor wafer,” “wafer,” “substrate,” “wafer substrate,” and “partially fabricated integrated circuit” are used interchangeably. One of ordinary skill in the art would understand that the term “partially fabricated integrated circuit” can refer to a silicon wafer during any of many stages of integrated circuit fabrication thereon. A wafer or substrate used in the semiconductor device industry may include a diameter of 200 mm, or 300 mm, or 450 mm. The foregoing detailed description assumes embodiments or implementations are implemented on a wafer, or in connection with processes associated with forming or fabricating a wafer. However, disclosed embodiments are not limited to such embodiments/implementations. The work piece may be of various shapes, sizes, and materials. In addition to semiconductor wafers, other work pieces that may take advantage of claimed subject matter and may include various articles such as printed circuit boards, or the fabrication of printed circuit boards, and the like.

Unless the context of this disclosure clearly requires otherwise, throughout the description and the claims, the words “comprise,” “comprising,” and the like are to be construed in an inclusive sense as opposed to an exclusive or exhaustive sense; that is to say, in a sense of “including, but not limited to.” Words using the singular or plural number also generally include the plural or singular number respectively. When the word “or” is used in reference to a list of 2 or more items, that word covers all of the following interpretations of the word: any of the items in the list, all of the items in the list, and any combination of the items in the list. The term “implementation” refers to implementations of techniques and methods described herein, as well as to physical objects that embody the structures and/or incorporate the techniques and/or methods described herein.

1. An apparatus to couple signals to a process chamber, comprising:
one or more first switches, positioned, when installed in the process chamber, between at least one energy storage device and at least one active element of the process chamber, and configured to control a first current conducted between the at least one energy storage device and the at least one active element of the process chamber; and
one or more second switches, positioned, when installed in the process chamber, between the at least one energy storage device and one or more current generators, and configured to control current conduction between the one or more current generators and the at least one energy storage device.

2. The apparatus of claim 1, further comprising one or more radiofrequency (RF) filters, each of the one or more RF filters in a series relationship with a corresponding one of the one or more first switches.

3. The apparatus of claim 2, wherein at least one of the one or more RF filters provides at least about 20 dB of signal attenuation at about 400 kHz or at about 27.12 MHz.

4. The apparatus of claim 1, wherein the at least one energy storage device comprises a capacitor or an inductor.

5. The apparatus of claim 4, wherein the capacitor comprises a capacitance from about 1 mF to about 100 mF or the inductor comprises an inductance from about 1 mH to about 100 mH.

6. The apparatus of claim 1, further comprising a transformer configured to increase a voltage from the at least one energy storage device.

7. The apparatus of claim 1, further comprising a controller coupled to the at least one energy storage device and configured to modify a value of capacitance or inductance of the at least one energy storage device.

8. The apparatus of claim 1, wherein the at least one energy storage device comprises 2 or more energy storage devices arranged in a parallel relationship.

9. The apparatus of claim 1, wherein the at least one active element of the process chamber comprises a resistive heating element, a microwave signal generator, an ultraviolet light source, an infrared light source, or any combination thereof.

10. The apparatus of claim 1, wherein the one or more first switches, a radiofrequency (RF) filter, the energy storage device, and the one or more one or more second switches are arranged in a series relationship with the one or more current generators.

11. The apparatus of claim 10, further comprising a controller configured to prevent closing of the one or more first switches and the one or more second switches at the same time.

12. A controller to control switching of one or more first of switches and one or more second switches, the controller comprising:
a processor, coupled to a memory, to direct opening of the one or more first switches positioned between at least one energy storage device and at least one active element of a process chamber,
the processor additionally to direct closing of the one or more first switches following, or simultaneous with, the opening of the one or more second switches positioned between the at least one energy storage device and one or more current generators.

13. The controller of claim 12, wherein the processor, after a duration, directs opening of the one or more second switches and, following or simultaneously with the opening of the one or more second switches, initiates closing of the one or more first switches.

14. The controller of claim 12, wherein the processor additionally operates to modify a value of capacitance or inductance of the at least one energy storage device.

15. The controller of claim 12, wherein the processor additionally directs closing of the one or more first switches responsive to an indication that the at least one energy storage device has accumulated a predetermined amount of energy.

16. A process chamber, comprising:
a first input port to receive a radiofrequency (RF) signal;
a resistive heating element at least partially disposed within the process chamber;
a current generator coupled to an energy storage device to supply an electric current to the resistive heating element;
a first switch, between the energy storage device and the resistive heating element, to interrupt a current coupled from the energy storage device to the resistive heating element; and
a second switch, between the current generator and the energy storage device, to interrupt a current coupled from the current generator and the energy storage device.

17. The process chamber of claim 16, further comprising a controller to: (i) open the first switch and to close the second switch to permit the energy storage device to accumulate charge from the current generator; or (ii) close the first switch and open the second switch responsive to the energy storage device storing a predetermined amount of charge.

18. The process chamber of claim 17, wherein the controller operates to ensure that the first switch and the second switch are not simultaneously closed.

19. The process chamber of claim 16, wherein the RF signal received by the first input port comprises a signal of about 400 kHz and/or a signal of about 27.12 MHz.

20. The process chamber of claim 16, wherein the process chamber comprises 2 or more wafer-processing stations.
